(19) United States
(12) Patent Application Publication
(10) Pub. No.: US 2005/0156656 A1
(43) Pub. Date: Jul. 21, 2005

(54) Non-quasistatic rectifier circuit

(76) Inventors: Robert R. Rotzoll, Chipita Park, CO (US); Klaus Dimmler, Colorado Springs, CO (US)

Correspondence Address: HOGAN & HARTSON LLP, ONE TABOR CENTER, SUITE 1500, 1200 SEVENTEENTH ST, DENVER, CO, 80202, US

(21) Appl. No.: 10/945,775

(22) Filed: Sep. 21, 2004

Related U.S. Application Data
(60) Provisional application No. 60/536,603, filed on Jan. 15, 2004.
(60) Provisional application No. 60/539,611, filed on Jan. 27, 2004.
(60) Provisional application No. 60/539,612, filed on Jan. 27, 2004.
(60) Provisional application No. 60/539,610, filed on Jan. 27, 2004.

(51) Int. Cl. H03K 17/56

(52) U.S. Cl. 327/423

(57) ABSTRACT

A non-quasistatic MOS rectifier circuit uses a bridge-rectifier configuration using four organic PMOS transistors, an antenna coil to induce a differential input signal, and an output capacitor for filtering the rectified output signal. The VSS or ground-connected transistors are diode-connected with the gate connection on the coil side of the transistor channel. The VDD-connected transistors have gates connected to the opposing VDD-connected transistor source that is connected to the coil. This configuration results in full-wave rectification. The gates are all connected to the coil and thereby become part of the capacitance of the radio frequency parallel resonant network. The transistor gates are then switched at the rate of the radio frequency signal with no delay relative to the coil voltage. Operation of the organic transistors is based on non-quasistatic behavior of the transistor. Non-quasistatic operation results in rectification at a frequency much higher than the quasistatic limit of transistor unity gain bandwidth.

The present application is related to and claims priority from U.S. Provisional Application Ser. No. 60/536,603, filed Jan. 15, 2004, entitled “Circuitry for the Design of RFID Tags in Polymer Electronic Processes”, 60/539,611, filed Jan. 27, 2004, entitled, “RFID Organic Process Methods”, 60/539,612, filed Jan. 27, 2004, entitled, “RFID Organic Circuit Designs”, and 60/539,610, filed Jan. 27, 2004, entitled, “RFID Organic Flexographic Printline Method”. The disclosures of all four provisional applications are herein specifically incorporated in their entirety by this reference.

### BACKGROUND OF THE INVENTION

1. Field of the Invention

The invention relates to organic transistors, and, more particularly, to a rectifier circuit and rectification method suitable for use given the performance constraints of organic transistors.

2. Description of the Related Art

Organic MOS transistors are similar to silicon metal-oxide-semiconductor transistors in operation. The major difference in construction is that the organic MOS transistor utilizes a thin layer of a semiconducting organic polymer film to act as the semiconductor of the device, as opposed to a silicon layer as used in the more typical in-organic silicon MOS device.

Referring now to FIG. 1, a cross-sectional diagram of a top-gate bottom contact organic MOS transistor 100 is shown. A metallic region 122 is deposited on an insulating substrate 112 forming the gate 122 of the organic MOS device 100. A thin dielectric region 120 is placed on top of gate region 122 to electrically isolate it from other layers and to act as the MOS gate insulator. Metallic conductors 118 and 116 are formed on the dielectric region 120 above the gate region 122 such that there is a gap 124 between conductors 116 and 118 overlapping gate metal 122. The gap 124 is known as the channel region of transitor 100. A thin film of organic semiconducting material 114 is deposited on dielectric region 120 and over at least a portion of metallic conductors 116 and 118. A voltage applied between the gate 122 and the source 118 modifies the resistance of the organic semiconductor film 114 in gap region 124 in the vicinity of the interface between semiconductor region 124 and dielectric 120. This is defined as the “field effect”. When another voltage is applied between the source 118 and the drain 116, a current flows between the drain and source with a value dependent on both the gate-to-source and the drain-to-source voltages.

The organic transistor 200 can also be constructed as a top-gate top contact structure as shown in FIG. 2. Conductor layer 222 is deposited and patterned on substrate 212. A dielectric layer 220 is deposited on conductor layer 222. A thin film of semiconductor material 214 is deposited on top of dielectric layer 220. A conductive film is deposited and patterned on top of organic semiconductor 2164 to form conductive source and drain regions 216 and 218, such that there is a gap 224 that overlaps the underlying gate metal layer 224. The gap 224 is known as the channel region of transistor 200. Through a field effect, a voltage is applied between gate conductor 222 and source 218 modifies the resistance of the organic semiconductor 214 in the gap region 224 in the vicinity of the interface between the semiconductor region 224 and the dielectric 220. When another voltage is applied between source 218 and drain 216, a current flows between the drain and the source with a value dependence on both the gate-to-source and the drain-to-source voltages.

Organic transistor 300 can also be constructed as a top gate structure as shown in FIG. 3. A conductive film is deposited and patterned on an insulating substrate 312 to form conductive regions 318 and 316. One of these conductive regions is known as the source 318, and the other as the drain 316. The gap 324 between them is known as the channel region of transistor 300. A thin organic semiconductor layer is deposited on top of these conductive regions such that the entire gap 324 and at least a portion of conductive regions source 318 and drain 316 are covered. A dielectric layer 320 is deposited on top of semiconductor layer 320. A conductive layer 322 is deposited and patterned such that at the underlying gap 324 and at least a portion of the source 316 and the drain 316 are covered. A field effect will cause the resistance of the organic semiconductor 320 inside the gap 324 in the vicinity of the interface between the semiconductor 320 and the dielectric 320 to decrease as a voltage is applied between the gate 320 and the source 318. When another voltage is applied between the source 318 and the drain 316, current will flow between the source 318 and the drain 316 the value of which depends on the voltage between gate 300 and the source 318.

In all of these structures, all layers may be patterned as long as the gate conductor overlaps the channel region gap and at least a portion of the source and drain, and organic semiconductor and dielectric are placed so that the gate conductor and the source/drain conductor are electrically isolated.

The organic semiconductor materials are often classified as polymeric, low molecular weight, or hybrid. Pentacene, hexithiphene, TPD, and PBD are examples of low weight molecules. Polythiophene, parathenylene vinylene, and polyphenylene ethylene are examples of polymeric semiconductors. Polyvinyl carbazole is an example of a hybrid matrial. These materials are not classified as insulators or conductors. Organic semiconductors behave in a manner that can be described in terms analogous to the band theory in inorganic semiconductors. However, the actual mechanics giving rise to charge carriers in organic semiconductors are substantially different from inorganic semiconductors. In inorganic semiconductors, such as silicon, carriers are generated by introducing atoms of different valencies into a host crystal lattice, the quantity of which is described by the number of carriers that are injected into the conduction band, and the motion of which can be described by a wave vector k. In organic semiconductors, carriers are generated in certain materials by the hybridization of carbon molecules in which weakly bonded electrons, called π electrons, becomes delocalized and travel relatively far distances from the atom which originally gave rise to that electron. This effect is particularly noted in materials comprising of conjugated molecules or benzene ring structures. Because of the delocalization, these π electrons can be loosely described as being in a conduction band. This mechanism gives rise to a low charge mobility, a measure describing the speed with which these carriers can move through the semiconductor, resulting in dramatically lower current characteristics of organic semiconductors in comparison to inorganic semiconductors.

Besides a lower mobility, the chemistry of carrier generation gives rise to another key difference between the operation of an organic MOS transistor and inorganic semiconductor. In the typical operation of an inorganic semiconductor, the resistance of the channel region is modified by an “inversion layer” consisting of the charge carriers made up of the type of charge that exists as a minority in the semiconductor. The silicon bulk is doped with the opposite type of carrier as compared to that used for conduction. For example, a p-type inorganic semiconductor built with an n-type semiconductor, but used p-type carriers, also called holes, to conduct current between the source and drain. In the typical operation of an organic semiconductor, however, the resistance of the channel region is modified by an “accumulation layer” consisting of charge carriers made up of the type of charge that exists as a majority in the semiconductor. For example, a PMOS organic transistor uses a P-type semiconductor and p-carriers, or holes, to generate the current in typical operation.

To fully understand the operation of a typical organic transistor, “non-quasistatic MOS transistor operation” must be explained. MOS transistors, both organic and inorganic, are normally assumed to allow immediate current flow between the source and drain of the device upon the application of a gate-to-source voltage. This is called the “quasistatic” assumption and allows for the development of a very simple transient-effect model of the MOS device. However, this assumption is only true when charge carriers are sufficiently mobile to response can be considered instantaneous in response to a change in input voltage characteristics. This assumption is only true when the transistor is operated at a frequency of operation substantially lower than the maximum frequency response of the charge carrier. Whereas this is true for most typical applications using inorganic semiconductors, this is not true for organic transistors operating at high speeds. When there is a significant delay between the application of gate-to-source voltage and the motion of the charge carriers giving rise to current the transient behavior of those charge carriers must be taken into account.

This delay has two components: a period with no current flow and a period of increasing current flow until a constant, stable current flow forms. This is shown in FIG. 4. The timing diagram of FIG. 4 includes a gate voltage pulse 424, a quasistatic drain current pulse 428, as is found in a conventional silicon MOS transistor, and a “non-quasistatic” drain current pulse 426 as is found in an organic transistor operating at high speed. Referring to voltage pulse 426, beyond the point where the current no longer increases, the device has quasi-static (“QS”) behavior. The delay region models non-quasistatic (“NQS”) behavior. This region is normally ignored because this delay is typically on the order of picoseconds for silicon MOS circuits that operate with pulse periods of one hundred or more picoseconds. Non-quasistatic behavior can be ignored in this case because the NQS delay is inconsequential relative to the signal periods of interest in a typical silicon MOS circuit. In organic transistors, this delay is on the order of ten nanoseconds, thereby requiring accounting of this effect when the transistor is operated in the hundreds of kilohertz and above range. The unity gain frequency of a transistor is defined as the frequency of operation at which the transistor is has an output voltage equal to the input voltage. When the transistor is operated below this frequency, the output voltage will be larger than the input voltage. When the transistor is operated above this frequency, the gain of the transistor is below unity meaning that the output voltage is less than the input voltage. Unity gain is always well below the frequency at which non-quasistatic behavior becomes an appreciable and measurable effect.

Though organic transistors have much lower performance than inorganic transistors, the materials and processing techniques to produce organic transistors cost significantly less those used to produce inorganic transistors. Therefore, organic transistor technology has application where low cost is desired and low performance is acceptable. Therefore, as the effective performance of an organic transistor is increased, the number of applications for organic transistor technology also increase. An example of this type of application are Radio Frequency Identification (RFID) tags. Though RFID tags can be produced at any frequency, it is desirable to produce RFID tag using frequency ranges that are used in typical applications. One such typical frequency for RFID tags is 13.56 Mhz, a frequency that is well above the unity gain frequency of organic transistors, and in the range where non-quasi-static behavior needs to be taken into account.

What is desired, therefore, is a practical circuit, such as a rectifier, that uses organic transistors operating at frequencies far above the unity gain bandwidth where non-quasi-static behavior needs to be taken into account.

### SUMMARY OF THE INVENTION

According to the present invention, a non-quasistatic MOS rectifier circuit uses a bridge-rectifier configuration using four organic PMOS transistors, an antenna coil to induce a differential input signal, an antenna resonating capacitor and an output capacitor for filtering the rectified output signal. The VSS or ground-connected transistors are diode-connected with the gate connection on the coil side of the transistor channel. The VDD-connected transistors have gates connected to the opposing VDD-connected transistor drain that is connected to the coil. The ground connected transistors conduct whenever the associated coil terminal voltage is negative with respect to ground. The result is that the coil voltage on the instantaneously negative coil terminal approaches the ground level. The VDD-connected transistors conduct current whenever the associated coil terminal voltage is greater than the voltage on the output capacitor. This action results in the output voltage approaching the peak AC coil voltage and is positive with respect to ground. This configuration, according to an embodiment of the present invention, results in full-wave rectification. There is loss of voltage through each transistor due to current flow into the load. The transistor gates are all connected to the coil and thereby become part of the capacitance of the radio frequency parallel resonant network comprising the antenna coil and antenna resonating capacitance. The transistor gates are then switched at the rate of the radio frequency signal and achieve the full signal voltage of the resonant network. Present organic transistors, however, demonstrate a signal loss at the desired operating frequency due to a very low transition frequency (f_{T}). Due to this condition, operation of these devices is based on non-quasistatic behavior of the transistor. As the gate voltage on the transistor exceeds its threshold voltage, a finite amount of time is required for the channel to be formed. In an embodiment of the present invention, the expected channel formation time is between 10 and 30 nanoseconds. After the channel is formed, current begins to build with a rough RC time constant due to distributed capacitance along the transistor channel. The circuit of the present invention operates as a rectifier because the amount of current required by the load during each AC coil voltage peak is fairly small and the channel formation time is less than the 36.9 nanoseconds determined by a half-cycle at the 13.56 MHz radio frequency on the coil.

### DESCRIPTION OF THE DRAWINGS

The present invention is illustrated by way of example and not by limitation in the accompanying figures in which like reference numerals indicate similar elements and in which:

FIGS. 1-3 are a cross-sectional views of an organic MOS transistors including an insulating substrate, organic polymer film, dielectric layer, and conductive gate;

FIG. 4 is a timing diagram showing a gate voltage pulse, as well as accompanying drain current responses for a quasistatic mode of operation as is found in an ideal silicon MOS transistor, and for a non-quasistatic mode of operation as is found in a typical organic MOS transistor;

FIG. 5 is a circuit diagram of a rectifier circuit according to a first embodiment of the invention including an antenna coil, an antenna resonating capacitor, an all-PMOS organic transistor circuit, and an output filter capacitor;

FIG. 6 is a timing diagram for the circuit of FIG. 3, including an input voltage waveform, an output voltage waveform, and an output current waveform;

FIG. 7 is a circuit diagram of a rectifier circuit according to a second embodiment of the invention including an antenna coil, an antenna resonating capacitor, an all-NMOS organic transistor circuit, and an output filter capacitor; and

FIG. 8 is a circuit diagram of a rectifier circuit according to a third embodiment of the invention including an antenna coil, an antenna resonating capacitor, a CMOS organic transistor circuit including both PMOS and NMOS transistors, and an output filter capacitor.

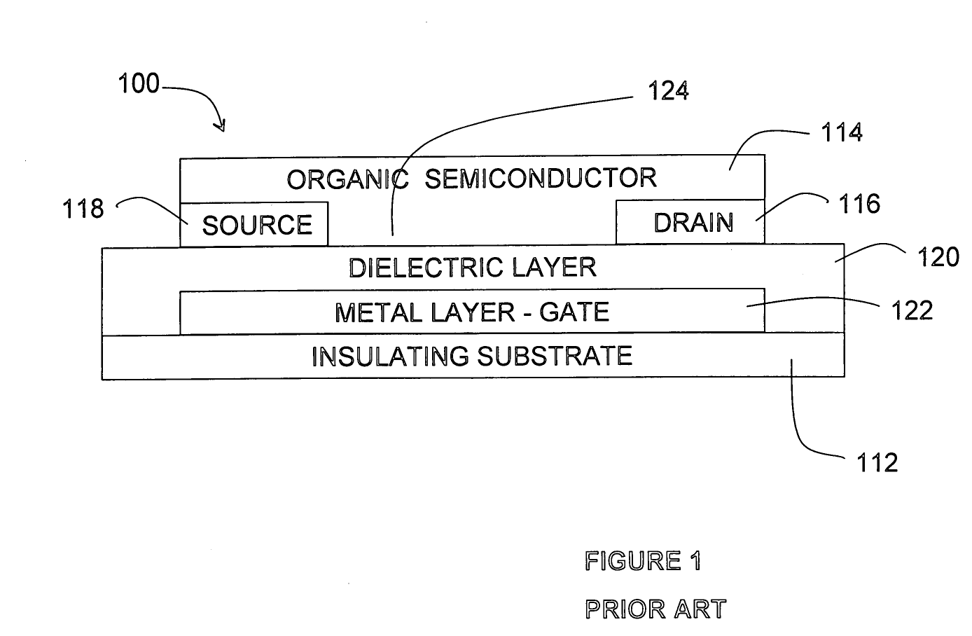

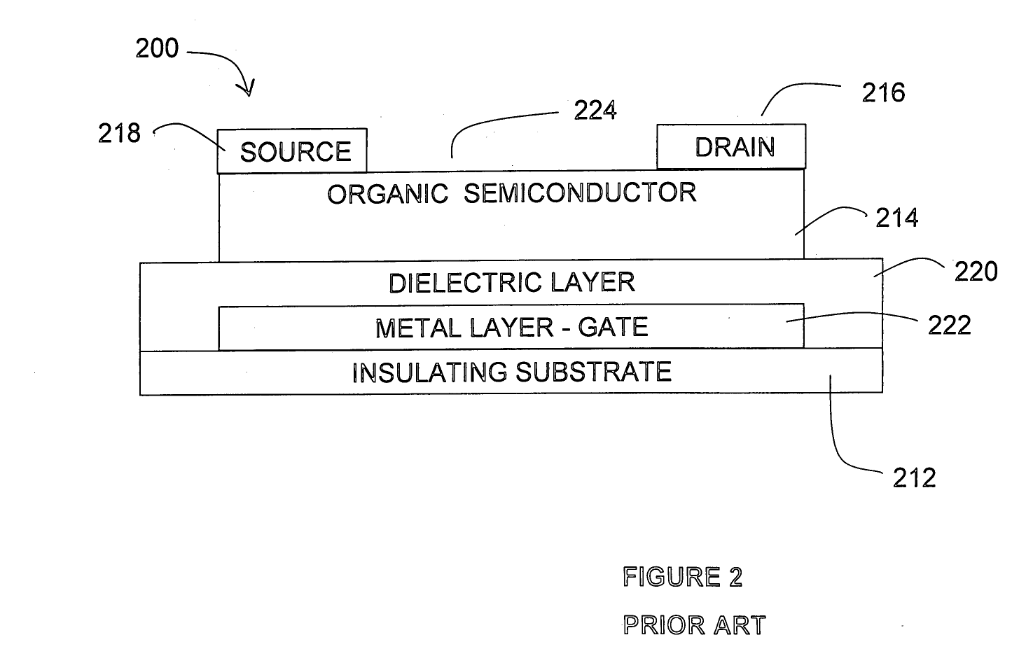

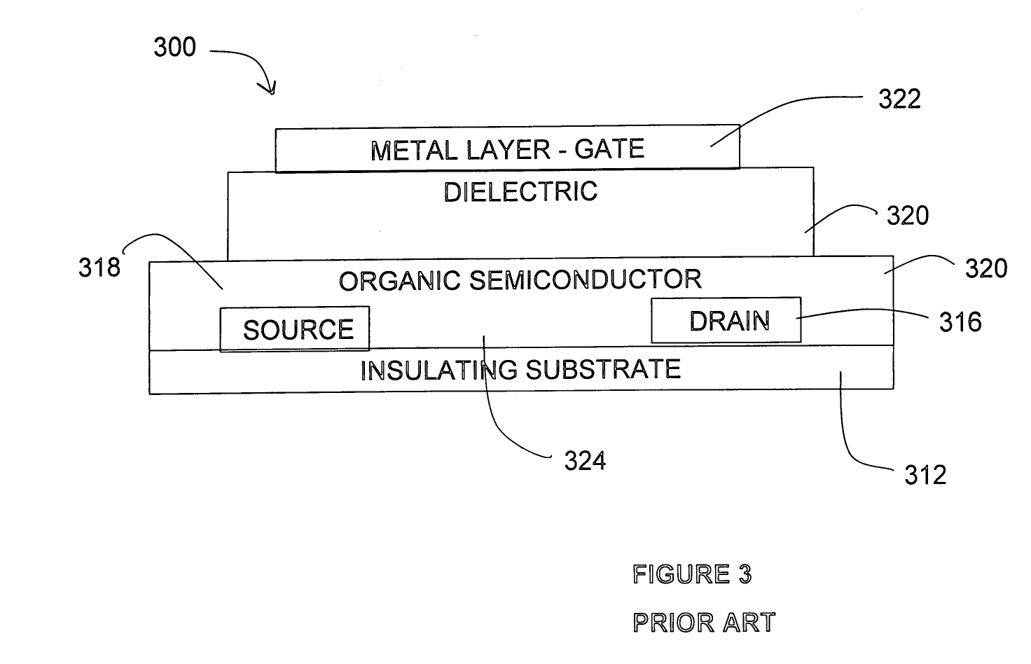

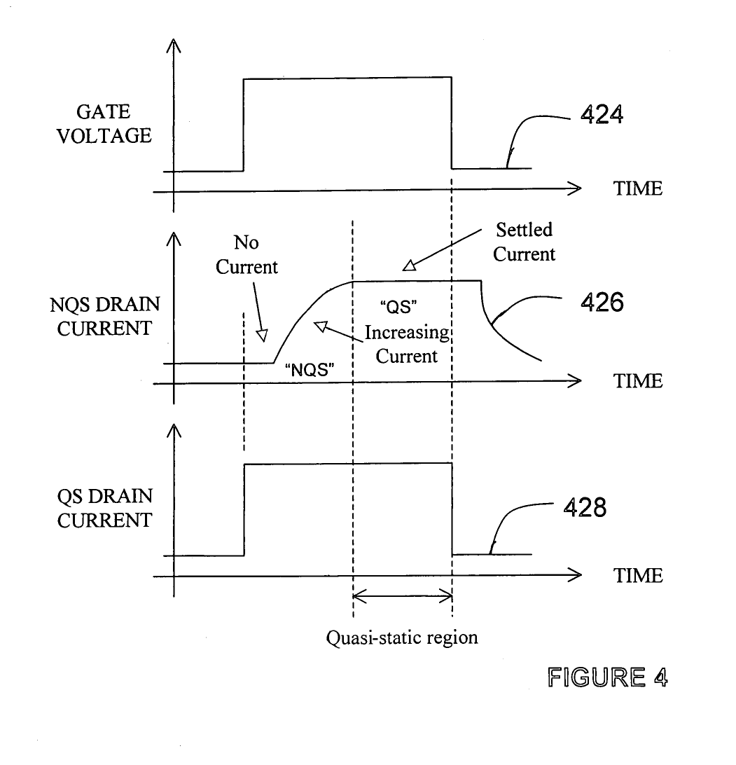

### DETAILED DESCRIPTION

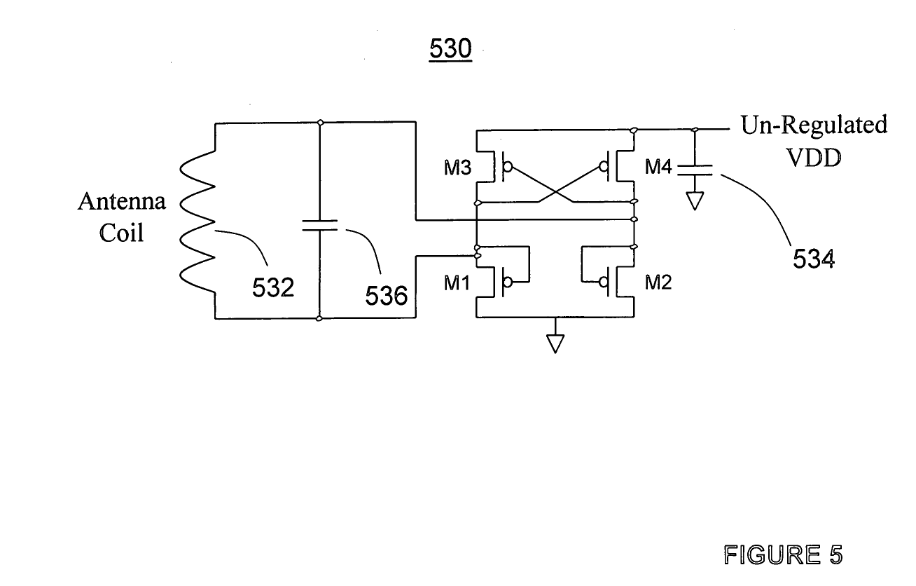

Referring now to FIG. 5 a rectifier circuit 530 according to a first embodiment of the present invention includes first and second input terminals for receiving a differential input signal from antenna coil 532 and an output terminal for providing a rectified output signal, which is filtered by capacitor 534. A capacitor 536 is coupled between the first and second input terminals. A first diode-connected PMOS transistor M1 is coupled between the first input terminal and ground, a second diode-connected PMOS transistor M2 is coupled between the second input terminal and ground, a third PMOS M3 transistor has a source coupled to the output terminal, a gate coupled to the second input terminal, and a drain coupled to the first input terminal, and a fourth PMOS transistor M4 has a source coupled to the output terminal, a gate coupled to the first input terminal, and a drain coupled to the second input terminal.

The transistors of RFID rectifier circuit 530 constructed using organic MOS transistors need not have gain at the signal frequency as in a traditional silicon-based circuit. Moreover, the signal drive to the gate of the transistor is in voltage mode from a parallel-tuned inductor-capacitor network. The capacitance of the gate is absorbed into the total capacitance of the tuned network. The result is that the gate voltage can be large depending on the Q, or quality factor of the network. The purpose of the rectifier circuit 530 is to charge a capacitor 534 with current in the proper direction so as to make the capacitor voltage equal to the peak voltage of the input alternating current (AC) signal.

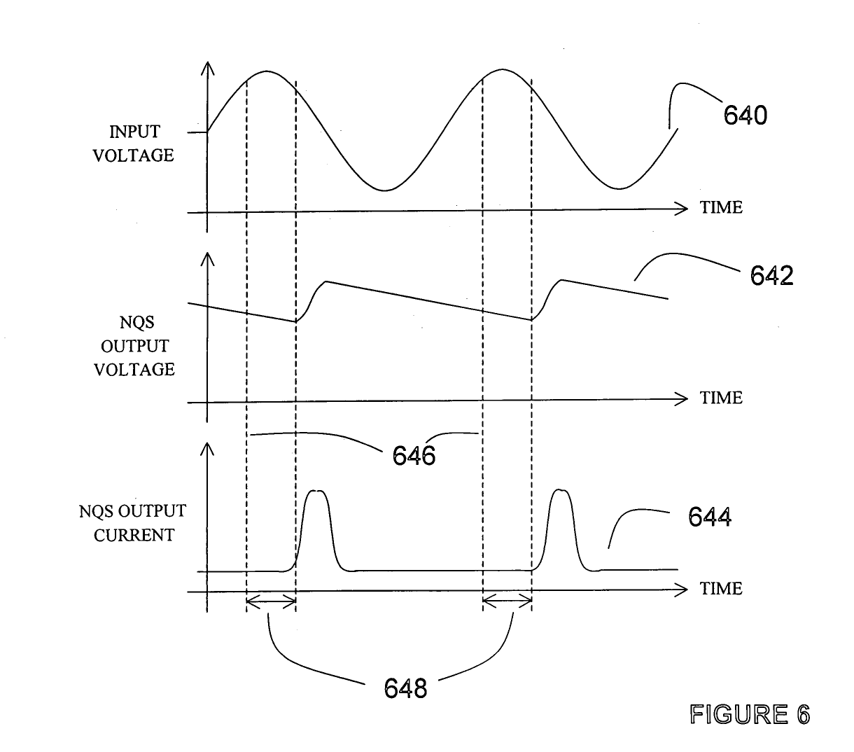

Non-quasistatic rectifier operation is shown in the timing diagram of FIG. 6. The alternating sine wave input voltage is shown in the top waveform 640. The second waveform 642 shows the delayed rectifier voltage response at the output capacitor 634. The third waveform 644 shows the delayed transistor current response (non-quasistatic “NQS” operation). Ideal operation without NQS effects (“QS” operation) would have the rectifier transistors pass current just prior to the peak of the incoming sine wave at point 646. The organic transistor, instead, does not pass current until the NQS delay 648 has occurred. This is still peak rectification, but the output voltage is lower than that of a circuit without NQS effects.

Rectifier voltage drop using the method of the present invention is defined as the sum of the voltage drop of the diode-connected transistors to VSS (M1 and M2 in FIG. 5) and the much smaller voltage drop across the devices that are switch-connected to VDD (M3 and M4 in FIG. 5).

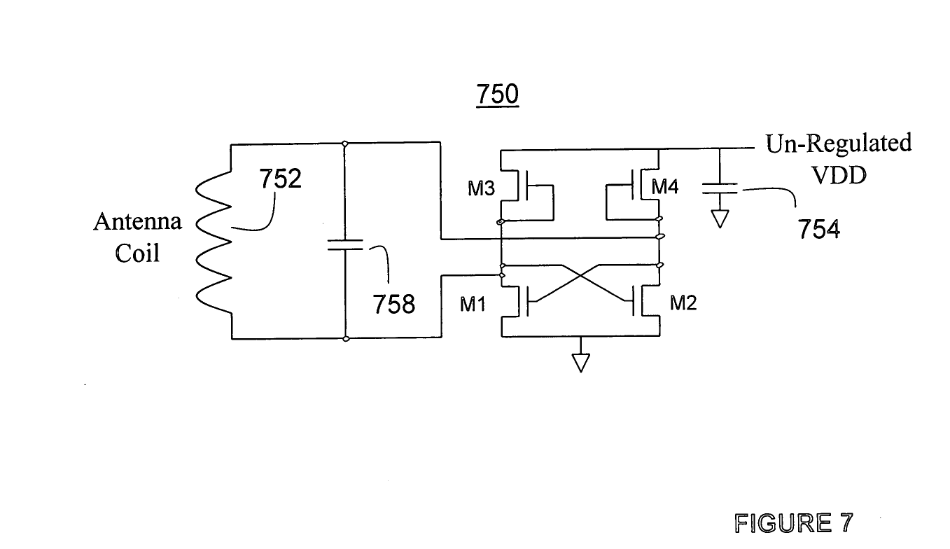

Alternative circuit configurations can be used other than the one shown in FIG. 5. Referring now to FIG. 7, a rectifier 750 uses an “all NMOS” circuit configuration in which all of the organic PMOS transistors are replaced with NMOS devices, and the VDD and VSS (ground) connections are swapped. In other words, transistors M3 and M4 are now the diode-connected transistors, and transistors M1 and M2 are now the switch-connected transistors. Transistors M3 and M4 are connected to VDD and transistors M1 and M2 are connected to VSS (ground). The result is a circuit 750 that is functionally equivalent to the all-PMOS circuit 530 shown in FIG. 5. The parametric performance is now related to the various characteristics of the NMOS transistor, for example the rectifier voltage drop is related to the threshold voltage of the NMOS transistor. Organic NMOS transistors operate in the non-quasistatic mode for a high excitation frequency, similar to the PMOS devices previously described.

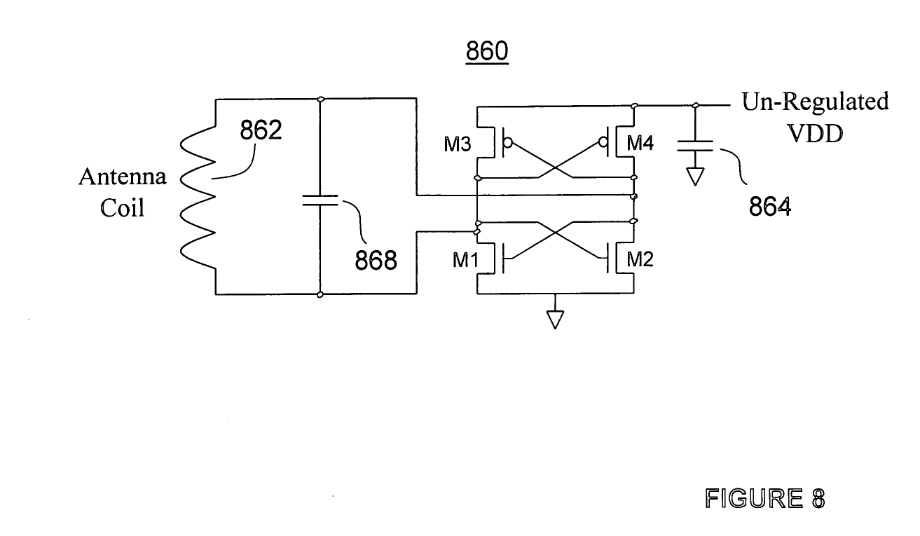

Referring now to FIG. 8, a CMOS switch-connected rectifier 860 is shown having switch-connected organic NMOS transistors M1 and M2 coupled between VSS and the input terminals, and switch-connected organic PMOS transistors M3 and M4 coupled between VDD and the input terminals. In this embodiment of the invention, the rectifier voltage drop is related to the sum of the PMOS switch voltage drop and the NMOS switch voltage drop. The switch voltage drops are much smaller than the diode connected voltage drop required in FIG. 5 and FIG. 7 implementations. The resulting rectifier voltage drop of FIG. 8 is therefore smaller than the other implementations.

There are numerous differences when comparing the rectifier circuits of 530, 750, and 860 FIGS. 5, 7, and 8 respectively to previous approaches using silicon-based transistors operating in the quasistatic mode. First, the organic transistors used in the present invention have a threshold such that the transistor conducts current for a zero gate-to-source voltage. Second, the organic device cannot conduct current immediately upon application of a gate-to-source voltage sufficient to cause channel current flow. Third, organic transistor mobility is very low and much less than that of other semiconductor technologies, such as silicon. Fourth, the organic transistor has no diffusion-to-substrate diodes. These are not the assumptions used for silicon process-based designs.

The first assumption is violated by all rectifier structures implemented in silicon. The first example is the pn-j unction diode. Conduction of this diode changes abruptly when a forward bias is placed across the junction. Below this level, and for reverse bias conditions, the current through the device is orders of magnitude below the forward conduction level. The diode is used in a manner such that current can flow with very low resistance during forward bias. A rectifier using this principle depends on a low, positive conduction voltage.

A second example is the silicon PMOS rectifier implemented using the same circuit topology as for the organic transistor. The VDD-connected PMOS switches turn off when the associated switch gate voltage is within a threshold voltage less than VDD. The organic transistor version of the present invention requires that the gate voltage rise above VDD by more than a threshold voltage level. Thus, the organic transistor circuit requires a larger input voltage swing to provide proper rectification.

Silicon-based devices essentially conduct full current within pico-seconds of the application of the associated gate voltage. Organic devices require tens of nanoseconds to do the same. For systems with frequencies above 100 kHz, this limitation results in much less current transfer through the organic device, requiring larger transistors.

Organic transistor mobility is two to three orders of magnitude lower than that of silicon. This implies that much larger transistor aspect ratios (transistor width divided by transistor length) are required for an organic device to pass an equivalent current to that of silicon. This results in a larger transistor and a corresponding increase in transistor gate capacitance. The gate capacitance increase due to low mobility and delayed application of current is cancelled by action of the RFID antenna inductance. In contrast, a silicon implementation does not have a very large gate capacitance and depends much less on the compensation effect of the antenna. An ideal aspect ratio for an organic NMOS transistor used in the present invention is between 10000 and 30000 assuming a semiconductor mobility of 0.1 centimeters per Volts-seconds, a gate capacitance of 9.6 nanofarads per square centimeter and a load current of 0.5 milliampere. An ideal aspect ratio for an organic PMOS transistor used in the present invention is between 10000 and 30000 assuming a semiconductor mobility of 0.1 centimeters per Volts-seconds, a gate capacitance of 9.6 nanofarads and a load current of 0.5 milliampere.

Silicon devices include a parasitic diffusion-to-substrate diode. This diode precludes the use of a combined PMOS and NMOS rectifier in applications not using special technologies such as silicon-on-insulator (SOI). In typical silicon CMOS processes, for example N-Well based processing, the N-Channel transistor diffusion-to-substrate parasitic diode would turn on when the associated coil voltage is negative and the N-channel transistor would not conduct. This condition is undesirable due to a large injection of carriers into the silicon substrate and sub-optimum turn-off time of the parasitic diode. Essentially, the N-channel transistor is not used, and other circuit elements may suffer due to substrate diode effects. The organic transistor process does not have this device and does not have substrate conduction issues. Therefore, an organic transistor circuit can use the combined PMOS and NMOS rectifier with no penalty.

While the invention has been described with respect to specific examples including presently preferred modes of carrying out the invention, those skilled in the art will appreciate that there are numerous variations and permutations of the above described systems and techniques that fall within the spirit and scope of the invention as set forth in the appended claims.

1. A rectifier circuit comprising a plurality of organic MOS transistors operating in a non-quasistatic mode of operation.

2. The rectifier circuit of claim 1 further comprising an antenna coil for providing a differential input signal.

3. The rectifier circuit of claim 1 further comprising a capacitor to provide sufficient additional capacitance beyond the gate capacitance of the MOS transistors to resonate the paralled tuned network to a predetermined frequency.

4. The rectifier circuit of claim 1 further comprising a load capacitor for filtering a rectified output signal.

5. The rectifier circuit of claim 1 comprising:
first and second input terminals for receiving a differential input signal;
an output terminal for providing a rectified output signal;
a first diode-connected PMOS transistor coupled between the first input terminal and ground;
a second diode-connected PMOS transistor coupled between the second input terminal and ground;
a third PMOS transistor having a drain coupled to the output terminal, a gate coupled to the second input terminal, and a source coupled to the first input terminal; and
a fourth PMOS transistor having a drain coupled to the output terminal, a gate coupled to the first input terminal, and a source coupled to the second input terminal.

6. The rectifier circuit of claim 1 comprising:
first and second input terminals for receiving a differential input signal; an output terminal for providing a rectified output signal;
a first diode-connected NMOS transistor coupled between the output terminal and the first input terminal;
a second diode-connected NMOS transistor coupled between the output terminal and the second input terminal;
a third NMOS transistor having a drain coupled to ground, a gate coupled to the second input terminal, and a source coupled to the first input terminal; and
a fourth NMOS transistor having a drain coupled to ground, a gate coupled to the first input terminal, and a source coupled to the second input terminal.

7. The rectifier circuit of claim 1 comprising:
first and second input terminals for receiving a differential input signal;
an output terminal for providing a rectified output signal;
a first NMOS transistor having a drain coupled to ground, a gate coupled to the second input terminal, and a source coupled to the first input terminal; and
a second NMOS transistor having a drain coupled to ground, a gate coupled to the first input terminal, and a source coupled to the second input terminal.
a first PMOS transistor having a drain coupled to the output terminal, a gate coupled to the second input terminal, and a source coupled to the first input terminal; and
a second PMOS transistor having a drain coupled to the output terminal, a gate coupled to the first input terminal, and a source coupled to the second input terminal.

8. The rectifier circuit of claim 1 wherein the large-signal input frequency of an input differential signal exceeds 1 MHz.

9. The rectifier circuit of claim 1 wherein the organic MOS transistor comprises an organic polymer field-effect transistor.

10. The rectifier circuit of claim 1 wherein the organic MOS transistors each comprise a semiconducting polymer films.

11. The rectifier circuit of claim 10 wherein the semiconducting polymer film comprises pentacene, hexithiphene, TPD, or PBD.

12. The rectifier circuit of claim 10 wherein the semiconducting polymer film comprises polythiophene, parathenylene vinylene, and polyphenylene ethylene, or polyvinyl carbazole.

13. The rectifier circuit of claim 1 in which the organic MOS transistors are operated at alternating current frequencies in excess of the unity gain bandwidth of the transistor.

14. A method of rectifying an input signal comprising operating a plurality of organic MOS transistors in a non-quasistatic mode of operation to iteratively supply a current pulse to a load capacitor.

15. The method of claim 14 wherein the method comprises operating a plurality of PMOS transistors.

16. The method of claim 14 wherein the method comprises operating a plurality of NMOS transistors.

17. The method of claim 14 wherein the frequency exceeds 1 MHz.

18. The method of claim 14 wherein the organic MOS transistors are operated at alternating current frequencies in excess of the unity gain bandwidth of the transistor.

19. A rectifier circuit comprising:
first and second input terminals for receiving a differential input signal;
an output terminal for providing a rectified output signal;
a first diode-connected organic PMOS transistor coupled between the first input terminal and ground;
a second diode-connected organic PMOS transistor coupled between the second input terminal and ground;
a third organic PMOS transistor having a drain coupled to the output terminal, a gate coupled to the second input terminal, and a source coupled to the first input terminal;
a fourth organic PMOS transistor having a drain coupled to the output terminal, a gate coupled to the first input terminal, and a source coupled to the second input terminal;
an antenna coil coupled between the first and second input terminals for providing the differential input signal; and
a load capacitor coupled between the output terminal and ground for filtering the rectified output signal.

20. The rectifier circuit of claim 19 in which each of the transistors comprises a transistor operating in a non-quasistatic mode of operation.
